(19) United States
(12) Patent Application Publication
(10) Pub. No.: US 2009/0079004 A1
(43) Pub. Date: Mar. 26, 2009

(54) METHOD FOR MAKING A TRANSISTOR WITH SELF-ALIGNED DOUBLE GATES BY REDUCING GATE PATTERNS

(75) Inventors: Christophe LICITRA, Grenoble (FR); Maud Vinet, Rives (FR)

Correspondence Address: OBLON, SPIVAK, MCCLELLAND MAIER & NEUSTADT, P.C., 1940 DUKE STREET, ALEXANDRIA, VA, 22314, US

(73) Assignee: COMMISSARIAT A L'ENERGIE ATOMIQUE, Paris (FR)

(21) Appl. No.: 11/561,174

(22) Filed: Nov. 17, 2006

(30) Foreign Application Priority Data
Nov. 18, 2005 (FR) 05 53510

(51) Int. Cl. H01L 21/336; H01L 29/78

(52) U.S. Cl. 257/365; 438/283; 257/E21.421; 257/E29.264

(57) ABSTRACT

This invention relates to an improved microelectronic method for making a double gate structure for a transistor, and particularly gate patterns (108a,128a,208a,228a,308a,328a) with a critical dimension less than the critical dimension of the transistor channel zone (104b). This method particularly includes a step to reduce double gate patterns, using isotropic etching. The invention also relates to a microelectronic device obtained using such a method.

### TECHNICAL FIELD AND PRIOR ART

This invention relates to the domain of integrated circuits and more particularly transistors, and its purpose is to describe a microelectronic device provided with at least one double gate structure for a transistor. In particular, the invention uses an improved method for making double gate transistors.

A classical transistor structure is usually formed on a substrate, for example of the SOI (Silicon on Insulator) type, a source region and a drain region, for example in the form of a first conducting zone and a second conducting zone respectively, joined together through a third semiconductor structure that will act as one channel or several channels in which a current will circulate, and that may be in the form of a block or a bar, or possibly several separate semiconducting bars. This or these semiconducting bars are covered by a semiconducting or metallic gate that can be used to control the intensity of a current passing through the channel, or possibly in the channels between the source region and the drain region.

In particular, new transistor gates structures have appeared so as to improve control over channel conduction. These new structures include the so-called double-gate structure that is formed from a first layer of gate material located under a semiconducting zone of the transistor channel, and a second layer of gate material located on the semiconducting transistor channel zone.

Document WO 03/075355 A1 presents a method for making a double gate structure including the formation of a dummy double-gate structure formed from a dummy gate pattern based on an insulating material, and another dummy gate pattern based on insulating material, then removal of said insulating material and replacement of this material by a gate dielectric and then by a gate material. The steps to deposit the gate dielectric and the gate material make the manufacture of gates with the same dimensions in the double gate structure difficult. Furthermore, with such a method, the gates of the double gate structure are formed from the same material.

The document by Lee J-H., Taraschi G., Wei A., Langdo T. A., Fitzgerald E. A., Antoniadis D. A., “Super Self-Aligned Double-Gate (SSDG) MOSFETs Utilizing Oxidation Rate Difference and Selective Epitaxy”, IEDM pp. 71-74>> presents a method for the formation of a double gate structure for a transistor, comprising the formation of a stack on a substrate provided with a first layer of gate material, a first layer of gate dielectric, a semiconducting layer in which the channel is to be made, a second layer of gate dielectric and a second layer of gate material. The stack is then etched through a mask to form the double gate patterns. A differential oxidation is then applied to make spacers, between the gate patterns for example made of polysilicon and the channel semiconducting zone for example made of silicon, followed by controlled deoxidation to expose the channel semiconducting zone. This method includes a high temperature oxidation step that could degrade the gate materials. Furthermore, it is difficult to deoxidize the channel semiconducting zone without removing the oxide from spacers formed on each side of the gates.

Document WO 03/103035 also discloses a method for making a double gate structure for a transistor. In particular, this method includes a step to form a first gate that will be called the <<lower>> gate in a layer of gate material in a stack also comprising a semiconducting layer in which a channel will be formed, a second layer of gate material, and an insulating layer; a step to form a channel zone in the semiconducting layer and a pattern in the insulating layer, using the lower gate as a mask. This method also includes bonding-turning over supports, followed by removal of said pattern formed in the insulating layer, and replacement by a gate material. This method also includes a step to selectively eliminate a silicon layer stopping on an undoped polysilicon layer, that is difficult to implement.

Document U.S. Pat. No. 6,365,465 presents a method for making a double gate structure for a transistor including the formation of a suspended channel structure, for example made of silicon, between source and drain zones, followed by photolithography to define the upper and lower gates of a double gate structure. With this method, the critical dimensions of the lower gate and the upper gate are different, the size of the lower gate being equal to the space between the source and the drain minus twice the thickness of the gate insulation, while the size of the upper gate is equal to the size of the gate lithography level. The transistor structure obtained using such a method includes source and drain zones isolated from the gates only by the gate dielectric, and it is then impossible to form spacers. With such a method, it is also difficult to reduce the gate patterns and obtain small critical dimensions.

Document JP-A-2001-102590 discloses a method for making a gate structure for a transistor including formation of a first gate vertically in line with a channel semiconducting zone by photolithography, and then production of an upper gate using a second photolithography operation. The disadvantages of this approach are that two different sized gates are formed, making alignment of said two gates difficult, particularly when the critical dimensions become very small, for example less than 20 nm.

Document FR 2 829 294 also discloses a method for making a double gate structure for a transistor and a plurality of spacers, particularly to protect the upper gate when the channel is being etched, to protect the channel when the lower gate is being etched, and to isolate the lower gate from the source and drain regions. The sizes of the upper and lower gates made using such a method are different.

The problem that arises is to find a new method for making a double gate structure for a transistor, that does not have the disadvantages mentioned above.

### PRESENTATION OF THE INVENTION

The purpose of this invention is to present a microelectronic device comprising at least one transistor provided with a double gate structure comprising a first gate or <<lower gate>> located under a channel zone of the transistor, a second gate or <<upper gate>> located on a channel zone of the transistor, first gate and second gate having respective critical dimensions equal or substantially equal similar to or lower than the critical dimensions of the channel. Critical dimensions <<approximately equal to>> or <<similar to>> means dimensions that are not different by more than two nanometers. The term <<critical dimension>> or <<minimum dimension>> as used throughout this description means the minimum dimension of a geometric pattern made in a thin layer, apart from the dimension(s) defined by the thickness of this thin layer.

The invention relates to a method for making a microelectronic device provided with at least one double gate structure for a transistor, including the following steps:

a) formation of at least one stack comprising at least one first layer of gate material (s), at least one first gate dielectric layer supported on the first layer of gate material(s), at least one semiconducting zone supported on said first gate dielectric layer, at least one second gate dielectric layer supported on said semiconducting zone and on said first gate dielectric layer, and at least one second layer of gate material(s) supported on said second gate dielectric layer,

b) etching, for example anisotropic etching, of said stack through a mask, so as to make at least one first structure facing the semiconducting zone, comprising a so-called <<channel>> semiconducting zone formed from said etched semiconducting zone, at least one first pattern of a first gate formed from the first etched layer of gate material, and at least one second pattern of a second gate formed from the second etched layer of gate material,

c) etching, for example isotropic etching, of at least part of the first pattern and at least part of the second pattern, selectively with regard to the channel semiconducting zone.

Isotropic etching in step c) is done to reduce the first gate pattern and the second gate pattern. After step b), the first pattern of the first gate, the second pattern of the second gate and the semiconducting zone formed have equal or approximately equal critical dimensions. After step c), the first pattern of the first gate, the second pattern of the second gate have critical dimensions less than the corresponding critical dimensions of the channel semiconducting zone.

In one variant, said first layer of gate materials may be formed from a stack of several sub layers of different materials.

Said stack may for example comprise at least one material that can be selectively etched with respect to the semiconducting zone and at least one other material chosen for its electricity conducting properties. This makes it possible to form gate patterns with critical dimensions smaller than the channel semiconducting zone, while having good control over the gate.

According to one possible embodiment, said second layer of gate materials may be formed from a stack of several sub layers of different materials.

According to one variant in which said first layer of gate materials is formed from a first stack of several sub layers of different materials and the second layer of gate materials is formed from a second stack of several sub layers of different materials, the first stack may be different from the second stack and/or may comprise at least one material different from the material from which the first stack is formed. In the case in which the first stack is formed from one or several materials different from the materials in the second stack, a lower gate and an upper gate can be formed with different electrical characteristics while having a critical dimension less than the critical dimension of the channel semiconducting zone.

According to another variant, the first stack and the second stack may be formed from the same materials but have different arrangements. The first stack and the second stack may be formed from a stack of two layers called the <<first bilayer>> and another stack of two layers called a <<second bilayer>> respectively, the second bilayer being formed from the same materials as the first bilayer but with a different arrangement from the arrangement of the first bilayer.

The first layer of gate material(s) and/or the second layer of gate material(s) may comprise at least one semiconducting material.

According to one variant, isotropic etching in step c) may include at least one dry etching step of said semiconducting material using a plasma.

According to one particular embodiment, said semiconducting material may be polySiGe.

The first layer of gate material(s) and/or the second layer of gate materials may include at least one sub layer based on at least one metallic material.

For example, the metallic material may be chosen from among Ti, TiN, W, WN, Ta, TaN.

According to one variant, isotropic etching in step c) may include at least one wet etching step using an SC2 type solution (SC2 stands for <<standard clean 2>>) based on HCl+H₂O₂+H₂O of said sub layer(s) based on metallic material.

According to one variant, said semiconducting zone may be based on silicon.

The anisotropic etching step b) may also comprise manufacturing of at least one second structure facing a zone or in a zone of the stack in which the second gate dielectric layer is supported on the first gate dielectric layer, the second structure comprising at least a third pattern joined to said first pattern, and formed from the first etched layer of gate material(s) and at least one fourth pattern joined to said second pattern, and formed from the second etched layer of gate material(s), the third pattern and the fourth pattern being separated by gate dielectric layers. Said second structure is joined to the first structure and may be used to act as zones for making contact for the first gate and for the second gate.

The method according to the invention may also comprise manufacturing of at least one first metallic contact in contact with said third pattern on said second structure without being in contact with said fourth pattern, for example after making the source and drain zones, and at least one second metallic contact in contact with the fourth pattern without being in contact with said third pattern.

The method may possibly also include the formation of insulating blocks or insulating spacers after step c), on each side of the first pattern of the first gate and on each side of the second pattern of the second gate.

Manufacturing of said insulating spacers may possibly include the following steps:
formation of at least one layer based on a first insulating material at least on the first structure,
formation of at least one second insulating material on the first insulating material,
anisotropic etching of the second insulating material,
partial removal of the first insulating material, so as to expose the channel semiconducting zone.

After step c), the method may also include the formation of at least one first zone that will act as the source region in contact with the channel semiconducting zone, and at least one second zone that will act as the drain region in contact with the channel semiconducting zone.

According to one variant, formation of said first zone and said second zone may include epitaxial growth of semiconducting blocks on the sides of the channel semiconducting zone. In this case, the semiconducting blocks may advantageously be based on a semiconducting material different from the semiconducting material(s) in the channel semiconducting zone.

According to a second variant, formation of said first source region zone and said second drain region zone may include the following steps:
deposition of at least one layer on the support, on the first structure, and possibly on said second structure,
production of cavities in said layer on each side of said first structure,
deposition of one or several metallic materials in the cavities, so as to form at least one first metallic block and at least one second metallic block on each side of the channel semiconducting zone.

According to a third variant, formation of said first source region zone and said second drain region zone may include the following steps:
epitaxial growth of at least one first semiconducting block and at least one second semiconducting block, on the corresponding sides of the channel semiconducting zone,
deposition of at least one so-called <<protection>> layer on the support,
production of cavities on each side of said first structure in the protection layer,
deposition of one or several metallic materials in the cavities so as to form at least one first metallic block on each side of the channel semiconducting zone, in contact with the first semiconducting block, and at least one second metallic block in contact with the second semiconducting block.

Formation of said stack in step a) may include the following steps:
deposit the first gate dielectric layer on a semiconducting layer supported on an insulating layer covering a first support,
deposit the first layer of gate material(s) on said first gate dielectric layer,
bond a second support onto the first layer of gate material(s),
remove the first support and part of said insulating layer covering the first support,
etch said semiconducting layer so as to form said semiconducting zone,
deposit second layer of gate dielectric on said semiconducting zone and on the first gate dielectric layer,
deposit the second layer of gate material(s) on the second gate dielectric layer,

The invention also relates to a microelectronic device comprising:
a support,
at least one first structure supported on a support comprising:
at least one first pattern of a first gate supported on the support and comprising a first stack of several sub layers of different gate materials,
at least a first layer of gate dielectric supported on the first pattern,
at least one so-called <<channel>> semiconducting zone with a critical dimension larger than the critical dimension of the first pattern, and in which a transistor channel can be formed,
at least one second gate dielectric layer supported on said semiconducting zone,
at least one second pattern of a second gate with a critical dimension less than the critical dimension of the semiconducting zone, the second pattern supported on the second gate dielectric layer and comprising a second stack of several sub layers of different gate materials.

According to one variant, the first stack may have an arrangement different from that of the second stack and/or may comprise at least one material different from the material in the first stack.

The first stack and/or the second stack may be formed from at least one semiconducting sub layer. The first stack and/or the second stack may also be formed from at least one metallic sub layer.

According to one variant embodiment, the first stack may be formed from a first metallic sub layer supported on a first semiconducting sub layer, and the second stack of a second semiconducting sub layer supported on a second metallic sub layer respectively, the composition of the first semiconducting sub layer being identical to the composition of the second semiconducting sub layer, and the composition of the first metallic sub layer being different from the composition of the second metallic sub layer.

The microelectronic device may also comprise at least one first zone that can form a transistor source region, at least one second zone that can act as a transistor drain region, the first zone and the second zone comprising at least a first semiconducting block and at least one second semiconducting block each formed by epitaxy on the channel semiconducting zone.

According to one variant, the microelectronic device may also comprise at least one first zone that can form one transistor source region, at least one second zone that can form a transistor drain region, the first zone and the second zone each comprising at least one first metallic block and at least one second metallic block in contact with said channel semiconducting zone.

According to another variant, the microelectronic device may also comprise at least one first zone that can form a transistor source region, at least one second zone that can form a transistor drain region, the first zone and the second zone comprising at least one first semiconducting block formed by epitaxy on the channel semiconducting zone, and at least one first metallic block in contact with said first semiconducting block respectively, the second zone comprising at least one semiconducting block formed by epitaxy on the channel semiconducting zone, and at least one second metallic block in contact with said second semiconducting block.

The microelectronic device according to the invention may also comprise insulating spacers on each side of the first pattern of the first gate and on each side of the second pattern of the second gate.

The microelectronic device according to the invention may also comprise at least one second contact making structure on the first gate and the second gate, the second structure being joined to said first structure and comprising:
at least one third pattern formed from said first stack of several sub layers of different gate materials,
at least one first gate dielectric layer supported on said third pattern,
at least one second gate dielectric layer supported on said first gate dielectric layer,
at least one fourth pattern formed from said second stack of several sub layers formed from different gate materials, and supported on said second gate dielectric layer.

The device according to the invention may also comprise at least one first metallic contact in contact with said third pattern without being in contact with said fourth pattern, and at least one second metallic contact in contact with the fourth pattern, without being in contact with said third pattern. Such contacts may be used to make a first gate pattern and a second gate pattern polarized independently. In other words, said first contact and said second contact may be useful for producing an upper gate and a second lower gate pattern with different polarizations.

### BRIEF DESCRIPTION OF THE FIGURES

This invention will be better understood after reading the description of example embodiments given purely for guidance and in no way limitatively, with reference to the appended figures, wherein:

FIGS. 1A to 1T, and 2A-2E, and 3A-3I illustrate a first example of a microelectronic method according to the invention,

FIGS. 4A to 4E illustrate a variant of the first example of a microelectronic method according to the invention,

FIGS. 5A and 5B illustrate another variant of the first example of a microelectronic method according to the invention,

FIGS. 6A to 6C illustrate another variant of the first example of the microelectronic method according to the invention,

FIGS. 7 and 8A-8C illustrate a variant embodiment of source and drain zones for a double gate transistor used according to the invention,

FIG. 9 illustrates a contact making structure for a double gate used according to the invention,

FIG. 10 illustrate a double gate transistor device provided with a contact for the upper gate of the double gate, and another contact for the lower gate of the double gate, the contact of the upper gate not being joined to or in contact with the lower gate, while the contact of the lower gate is not joined to or in contact with the upper gate.

Identical, similar or equivalent parts of the different figures have the same numeric references so as to facilitate comparison between the various figures.

The different parts shown on the figures are not necessarily shown at the same scale, to make the figures more easily understandable.

### DETAILED PRESENTATION OF PARTICULAR EMBODIMENTS

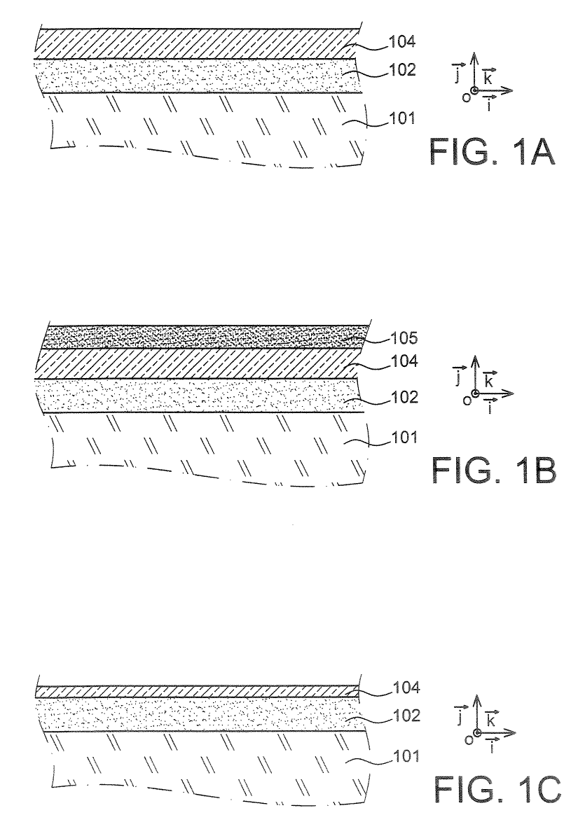

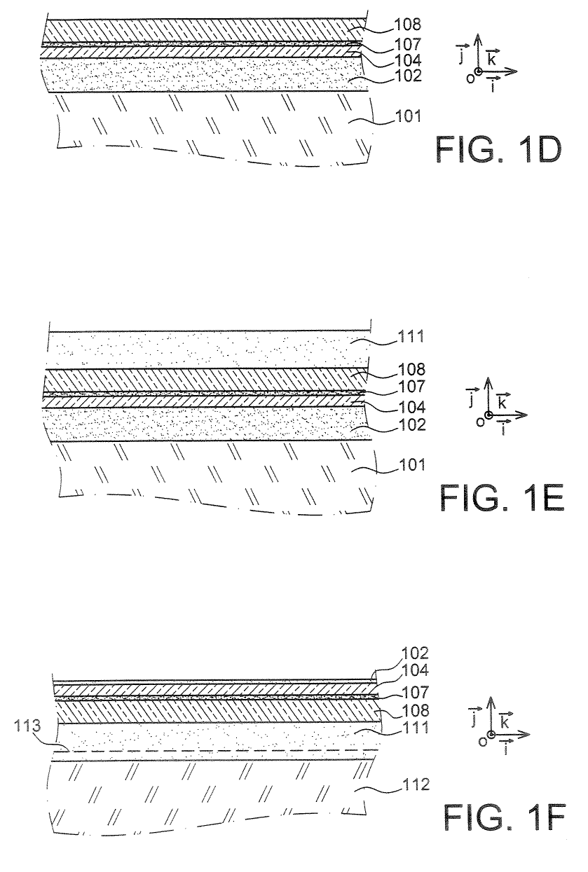

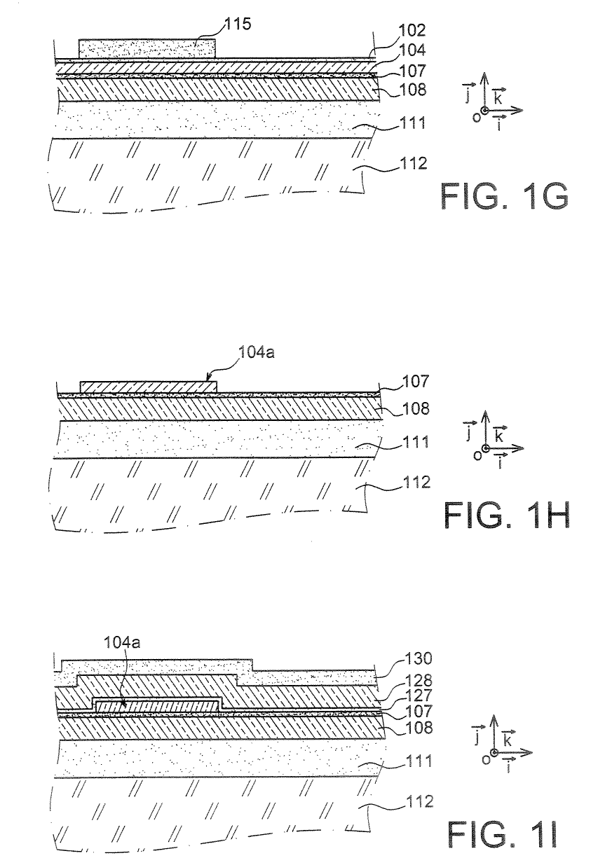

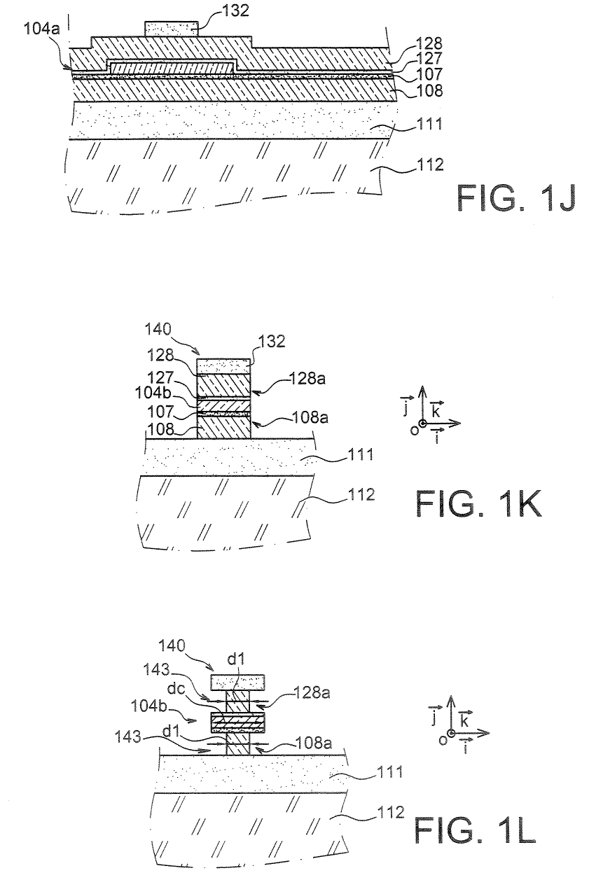

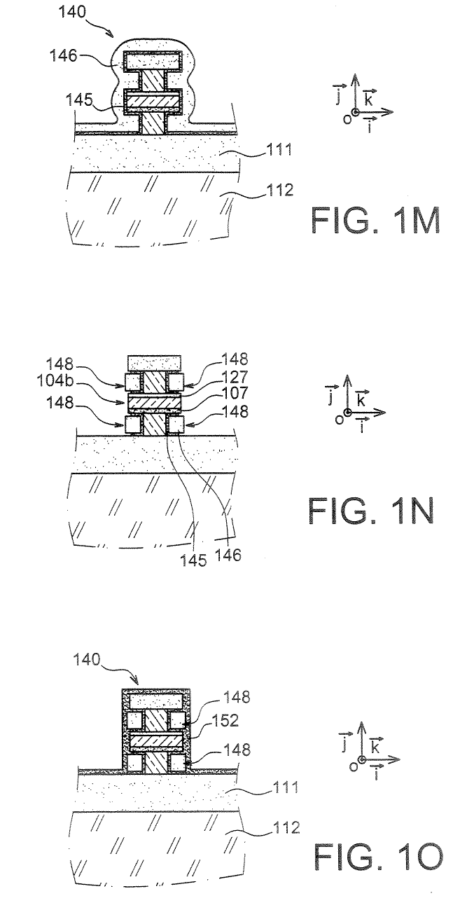

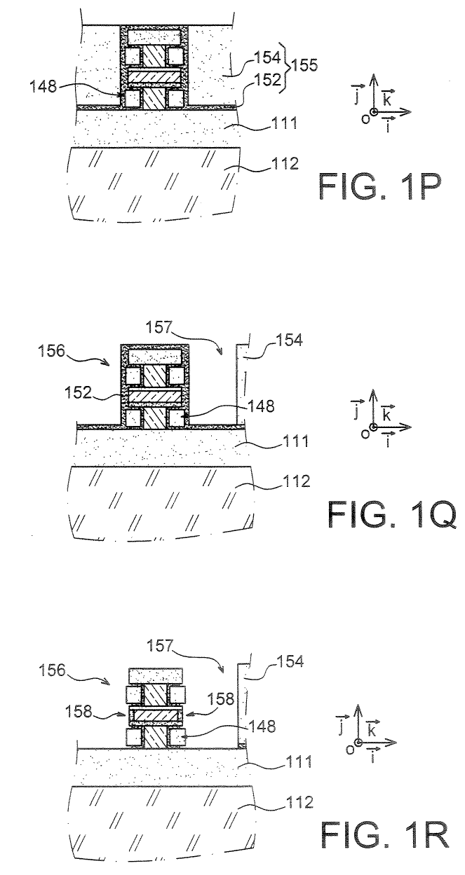

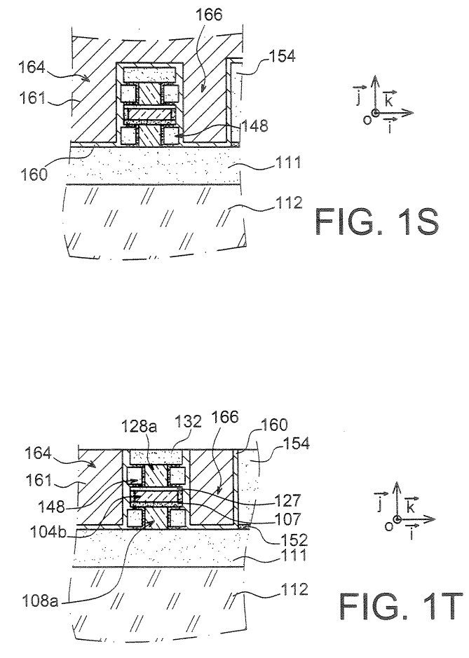

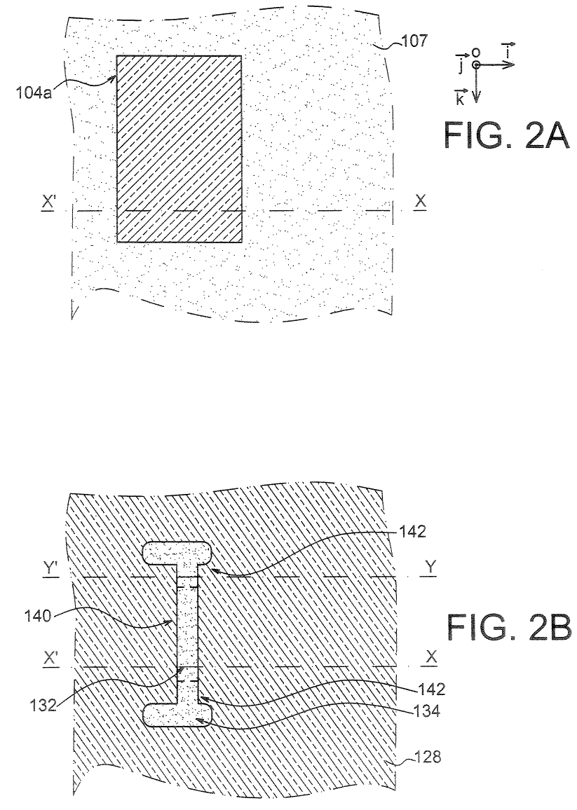

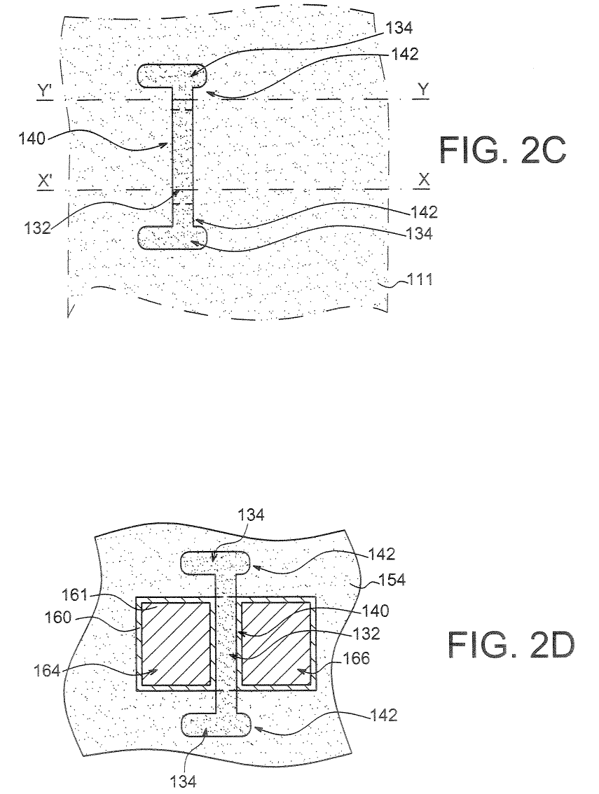

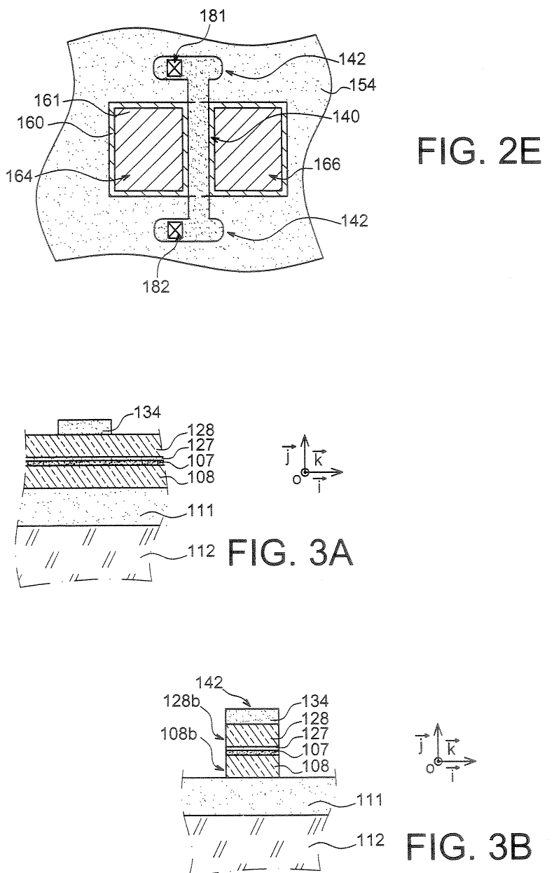

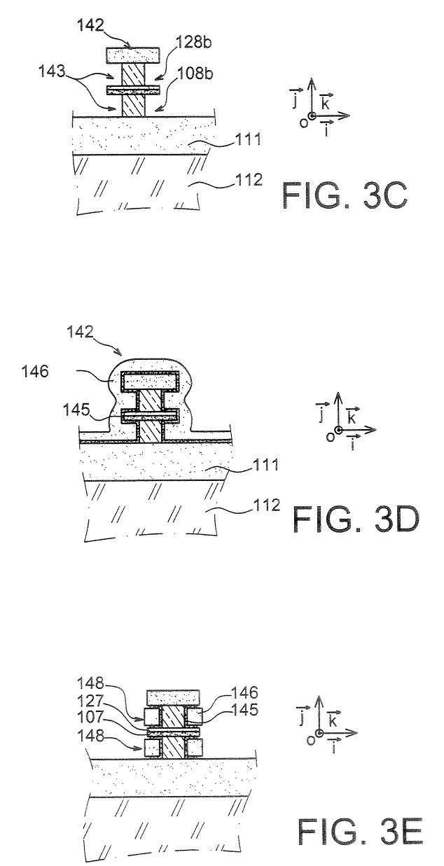

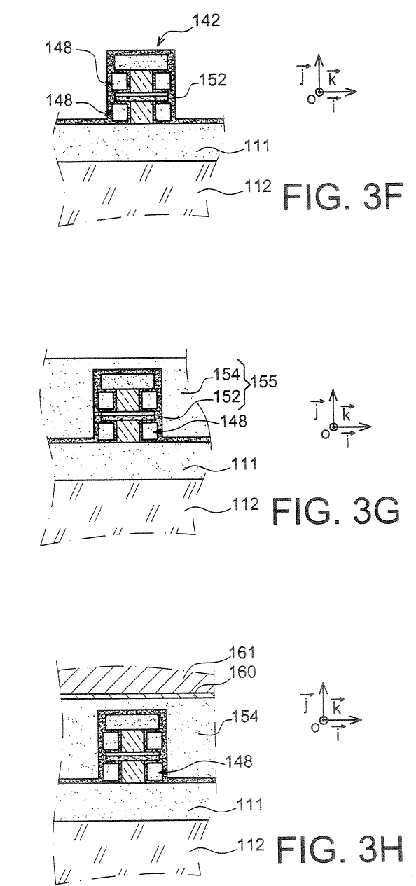

An example method according to the invention for making a microelectronic device provided with at least one double gate structure for a transistor will now be given with reference to FIGS. 1A-1T representing the device during manufacturing seen on a first section X′X, and FIGS. 2A-2E representing a top view of said device and FIGS. 3A to 3I representing a second section Y′Y, the sections X′X and Y′Y being taken in planes parallel to the [O; \vec{i}; \vec{j}] plane of an orthogonal coordinate system [O; \vec{i}; \vec{j}; \vec{k}] shown on FIGS. 1A-1T, 2A-2E and 3A-3I.

For example, the initial material may be a substrate that may be of the semiconductor on insulator type, for example an SOI (silicon on insulator) substrate or a germanium on insulator (GeOI) substrate or an SiGe on insulator (SiGeOI) substrate. The substrate may include a layer 101 that will be called the <<first support>>, for example based on a semiconducting material such as silicon on which an insulating layer 102 is supported, for example a buried oxide layer based on SiO₂, itself covered with a semiconducting layer 104. The semiconducting layer 104 may for example be based on silicon, or germanium or SiGe (FIG. 1A).

A step to thin this semiconducting layer 104 may then be made for example by oxidation of the semiconducting material of layer 104 so as to form a thickness 105 of semiconducting oxide, then by removal of this oxide thickness 105, for example by HF. For example, the thinned semiconducting layer 104 may be between 5 and 10 nanometers thick (FIGS. 1B and 1C).

A dielectric gate layer 107 is then deposited that will be called the <<first gate dielectric layer>>. The dielectric layer 107 may for example be between 1 and 5 nanometers thick and may for example be formed from a so-called high dielectric constant material or high-k material, for example made of HfO₂ or Al₂O₃.

A layer 108 of gate material is then deposited that will be called the <<first gate material layer>>. The gate material used to form the layer 108 was chosen so that it can be selectively etched with respect to the semiconducting layer 104. The first layer of gate material may for example be formed from a semiconducting material such as polySiGe, particularly in the case in which the semiconducting layer is based on Si (FIG. 1D).

The next step is to form another insulating layer 111 called the <<bonding>> layer, for example based on SiO₂, on the first layer 108 of gate material (FIG. 1E). A second support is then bonded onto the insulating layer 111, for example using an oxide to oxide type bonding method like that presented in the document entitled <<the bonding energy control: an original way to debondable substrate>>, Electrochemical society conf., Paris, May 2003 Wafer bonding Symposium>>. The second support may for example be formed from a second insulating layer (not referenced) supported on another layer 112, for example a semiconducting layer.

The next step is to remove the first support 101, for example using polishing and then chemical etching based on TMAH, and at least part of the thickness of the insulating layer 102, for example using HF. According to one variant embodiment, the bonding interface 113 between the insulating layer 111 and the insulating layer of the second support may for example be located at not less than 300 or 350 or 400 nanometers from layer 108 (FIG. 1F).

The next step is to make a mask on the insulating layer 102 and above or facing the semiconducting layer 104, comprising at least one pattern of the active transistor zone. For example, this mask may be formed by deposition of a resin layer 115 on the remaining thickness of the insulating layer 102, and then formation of the active zone pattern in the resin layer 115 (FIG. 1G) for example by photolithography.

The next step is to etch the semiconducting layer 104 and the insulating layer 102 through the mask, so as to reproduce the pattern of the active zone in this layer 104. The etched semiconducting layer will be referenced 104a and will be called the <<semiconducting zone>>. A transistor channel will be made in at least part of this semiconducting zone 104a. Anisotropic etching, for example dry plasma etching based on Cl₂ (+O₂) or HBr (+O₂) may be done through said resin mask 115, to the level of the first gate dielectric layer 107, to form the semiconducting zone 104a.

The mask 115 and the insulating layer 102 are then removed. The device formed then comprises at least one semiconducting zone 104a on the surface and at least one so-called <<insulation>> zone formed by the first gate dielectric layer 107 (FIGS. 2A and 1H, these figures representing a top view of the microelectronic device during manufacturing, and a view on section X′X of this device respectively, the section X′X being shown on FIG. 2A and taken in a plane parallel to the [O; \vec{i}; \vec{j}] plane in the orthogonal coordinate system [O; \vec{i}; \vec{j}; \vec{k}]).

The next step is to deposit another insulating layer 127 called the <<second gate dielectric layer>> on the semiconducting zone 104a and on the dielectric layer 107. The next step is to deposit a layer of gate material that will be called the <<second gate material layer>>. The second layer 128 of gate material may for example comprise a semiconducting material. The gate material used to form the second layer 128 of gate material was chosen so that it can be etched selectively with respect to the semiconducting layer 104. For example, in a case in which the semiconducting zone 104a is based on silicon, the second layer 128 of gate material may for example be based on polySiGe. According to one variant embodiment, the first layer 108 of gate material and the second layer 128 of gate material may have exactly the same composition and/or be based on the same material. The first layer 108 of gate material and the second layer 128 of gate material may also have equal or approximately equal thicknesses. The next step is to form another mask layer 130 on the second layer 128 of gate material (FIG. 1I). The other mask layer 130 may for example be based on SiO₂. The next step is to make at least one first pattern 132 in the form of a gate in a region of said other mask layer 130 located facing the semiconducting zone 104a and at least one second pattern 134 joined to the first pattern 132, for example by photolithography, and in the form of one or several contact making zones in at least one region of the mask layer 130 facing the insulation zone 122. According to one variant, the second pattern 134 may be formed from two parts on each side of the first pattern (FIGS. 1J, 2B and 3A representing a view on section X′X, a top view, and another view on section Y′Y of the microelectronic device being manufactured).

The next step is etching through patterns 132 and 134 of the mask layer in a stack comprising the second layer 128 of gate material, the second gate dielectric layer 127, the semiconducting zone 104a, the first gate dielectric layer 107, the first layer 108 of gate material. Etching of said stack is done so as to reproduce the form of said patterns 132 and 134 in said stack and to expose the insulating support layer 111. Said etching of the stack may be anisotropic etching made for example using plasma etching, for example based on Cl₂ (+O₂) or HBr+(O₂) or BCl₃.

The etched semiconducting zone 104a will now be called the channel semiconducting zone and will be referenced 104b. This channel semiconducting zone reproduces the form or the design of the first gate pattern 132. After the stack has been etched, a first structure 140 was formed comprising patterns 108a, 128a of a double gate under and on the channel semiconducting zone 104b respectively. A second structure 142 joined to the first structure 140 and reproducing the second pattern of contact making zones was also formed and includes patterns 108b, 128b based on the first layer 108 of gate material, and the second layer 128 of gate material respectively, separated by zones derived from the dielectric layers 107 and 127 (FIG. 1K representing a view on section X′X, FIG. 2C representing a top view, and FIG. 3B representing another view on section Y′Y of the microelectronic device during manufacturing.

The next step is to etch the patterns 108a, 128a, 108b, 128b of gate material under the masking patterns 132 and 134, selectively with regard to the channel semiconducting zone 104b. This etching may be isotropic etching, for example dry etching done using plasma. For example, a CF₄ based plasma may be used. This isotropic etching may be used to laterally reduce the patterns 108a, 108b, 128a, 128b, or to reduce the critical dimension of the double gate patterns 108a, 128a, and patterns 108b and 128b of the second structure 142.

After this isotropic etching, the critical dimensions d₁ of patterns 108a, 128a, 108b, 128b are equal to or approximately equal to each other (the critical dimension being a dimension measured along a direction parallel to the direction defined by a vector \vec{i} in the orthogonal coordinate system [O; \vec{i}; \vec{j}; \vec{k}]). The critical dimension d₁ of the etched patterns 108a, 128a, 108b, 128b is less than the critical dimension dc of the channel zone 104a (the critical dimension of the active zone dc being a dimension measured along a direction parallel to the direction defined by a vector \vec{i} of the orthogonal coordinate system [O; \vec{i}; \vec{j}; \vec{k}]). Selective etching of patterns 108a, 128a, 108b, 128b with regard to the semiconducting zone 104a also provides a means of forming cavities 143 on each side of the patterns 108a, 128a, 108b, 128b (FIG. 1L representing a view of the microelectronic device being manufactured on section X′X, and FIG. 3C representing a view on section Y′Y).

The next step can then be to dope the ends also called <<extensions>> of the semiconducting zone 104b. The <<ends>> of the semiconducting zone 104b means regions of this semiconducting zone 104b that are not located between the patterns 108a and 128a of the double gate and that project beyond the patterns 108a and 128a of the double gate. For example, the extensions may be doped using at least one implantation. This implantation may be done at a non-zero angle with a normal to the principal plane of the insulating layer 111 (the principal plane of the insulating layer being defined by a plane passing through this layer 111 and parallel to the plane [O; \vec{i}; \vec{k}] on FIG. 1L).

The next step (FIG. 1M representing a view on section X′X, and FIG. 3D representing another view on section Y′Y) is to form insulating zones or insulating spacers 148 on each side of the patterns 108a, 128a, 108b, 128b, by deposition of one or several dielectric materials in the cavities 143.

These spacers 148 may be made firstly by deposition, for example a conforming deposition, of a thin layer, for example of the order of 5 nanometers thick based on a first insulating material 145, for example SiO₂, and then by deposition, for example a conforming deposition, of a second insulating material 146 for example made of Si₃N₄, on the structures 140 and 142. The thickness of the second deposited insulating material 146 is chosen so as to fill in the cavities 143. The thickness of the second deposited insulating material 146 may be chosen to be greater than or equal to half the depth of the cavities 143 (the cavity depth 143 being a dimension defined in a direction parallel to the vector \vec{j} in the orthogonal coordinate system [O; \vec{i}; \vec{j}; \vec{k}] on FIGS. 1M and 3D).

The second insulating material 146 can then be anisotropically etched, for example using an HBr based plasma. The next step is to partly remove the first insulating material 145, so as to expose the channel semiconducting zone 104b. For example, this removal can be done by etching using hydrofluoric acid. After these etching operations, insulating zones 148 based on the second insulating material 146 and the first insulating material 145 are formed in said cavities 143, on each side of the patterns 108a, 128a, 108b, 128b (FIGS. 1N and 3E representing a view on section X′X, and a view on section Y′Y respectively).

The next step is to form source and drain regions on each side of the channel semiconducting zone 104b, on the sides of this semiconducting zone 104b.

This can be done firstly by depositing a thin layer (or <<liner>>) that may be insulating, for example based on SiO₂ and of the order of several nanometers thick, for example 5 nanometers thick, and then another insulating layer called the <<stop layer>> (not referenced), for example based on Si₃N₄ and of the order of several nanometers thick, for example 30 nanometers thick, so as to form a layer 152 that may be insulating and conforming, on the insulating layer 111 and on the structures 140 and 142 (FIG. 1O representing a view on section X′X and, and FIG. 3F representing a view on section Y′Y).

The next step is to form a thick layer 154 that may be insulating and for example based on SiO₂, of the order of a hundred nanometers thick, for example 300 nanometers thick. The thickness of the layer 154 is chosen so as to be at least equal to or greater than the height of the second structure 142, so as to cover this structure (the height of the structure being a dimension measured along a direction parallel to the vector \vec{j} in the orthogonal coordinate system [O; \vec{i}; \vec{j}; \vec{k}]). If the thickness of the layer 154 is greater than the height of the first structure 140, the thickness of the layer 154 above the structures 140 and 142 can be reduced to the insulating thickness 152 covering the top of the first structure 140, for example using a CMP (<<Chemical Mechanical Polishing>>) step stopping on the layer 152 and particularly on the Si₃N₄ based stop layer (FIGS. 1P and 3G).

In the next step (FIG. 1Q), cavities 156, 157 are formed in the layer 154 on each side of the first structure 140. The cavities 156, 157, expose the first structure and are made so as to form an active zone pattern that may be identical to the pattern 104a formed in the semiconducting layer 104, during a step previously described with reference to FIG. 1H. The cavities 156, 157 may for example be made by photolithography and anisotropic dry etching, for example by means of a plasma. The next step is to remove the insulating layer 152 covering the structure 140 in the cavities 156, 157 (FIG. 1R). This removal may be done for example using an H₃PO₄ based etching so as to remove the thin insulating layer based on SiO₂, and an HF-based etching so as to remove the stop layer based on SiO₂. The cavities 156, 157 formed in layers 152 and 154 expose the first structure 140, and particularly the ends of the channel semiconducting zone 104b.

Before the source and the drain blocks are made, conducting zones can be formed in a part of the ends of the semiconducting zone 104b. To achieve this, part of the ends of the semiconducting zone 104b can be silicided. This siliciding can improve future contacts firstly between a future source region and the channel semiconducting zone 104b, and secondly between a future drain region and the channel semiconducting zone 104b. Siliciding may for example comprise a nickel deposit on the exposed parts of the channel structure 104b, followed by a siliciding annealing, then selective removal of unconsumed Ni so as to form NiSi based zones 158 at part of the ends of the semiconducting zone 104b (FIG. 1R).

The next step is to form metallic blocks 164, 166, on each side of the first structure 140 that will act as source region and drain region. This can be done by making one or several depositions of metallic materials in the cavities 156, 157. Formation of the blocks 164, 166 may include deposition of a thin layer of metal 160, for example TiN, then deposition of another metal layer 161, for example based on W, or WSi, on each side of the first structure 140.

In one case (FIGS. 1S and 3H) in which the deposited metal layers 160 and 161 project beyond the first structure 140 and/or the metallic blocks 162, 164 are adjacent to or are joined to each other, these layers 160, 161 can be partially removed, particularly above the first structure 140, so as to form separate metallic blocks 162 and 164. This partial removal can thus eliminate any bond or possible short circuit between the source and drain regions. For example, this partial removal can be done using a CMP step on layers 160 and 161, for example stopping on the insulating pattern 132.

FIG. 1T illustrates a view on section X′X of a microelectronic double gate transistor device after formation of the source and drain metallic blocks 164, 166, FIG. 2D illustrates a top view, and FIG. 3F illustrates a view on section Y′Y. This microelectronic device comprises at least a first structure provided with a channel semiconducting zone 104b, and patterns 108a and 128a of a first so-called <<lower gate>> and a second so-called <<upper gate>> structure respectively, formed above and below the semiconducting zone 104b respectively. The lower gate 108a is separated from the channel semiconducting zone 104b by the first gate dielectric material 107, while the upper gate 128a is separated from the channel semiconducting zone 104b by a second gate dielectric layer 127. The critical dimensions or minimum dimensions d₁ of the upper gate 128a and the lower gate 108a are equal or approximately equal. The critical dimension d₁ of the lower and upper gates is less than the critical dimension or the minimum dimension dc of the semiconducting zone of channel 104b. The device also comprises metallic source and drain blocks 162 and 164, formed on each side of the channel zone 104b and are in contact with the ends of this zone 104b. The metallic source and drain blocks 162 and 164 are isolated or separated from the double gate patterns 108a, 128a by insulating spacers 148, formed on each side of the patterns 108a, 128a, and in contact with them. The first structure 140 may also comprise or be covered with an insulating pattern 132 reproducing the form of the channel (FIGS. 1T and 2D). The device also comprises a second structure 142 joined to the first structure 140, and comprising a third pattern 108b and a fourth pattern 128b joined to the first pattern 108a and to the second pattern 128a respectively, and based on gate material. The third pattern 108b and the fourth pattern 128b are separated by gate dielectric based zones 107, 127 (FIG. 3I).

The second structure may be used as contact making zones to polarize the double gate. The method may also comprise manufacture of at least one first contact 181 on part of the third pattern 108b formed from the first layer 108 of gate material, and at least one second contact 182 on part of said fourth pattern 128b formed from the second layer 128 of gate material on the second structure, for example after the source and drain semiconducting zones have been manufactured, the first contact 181 not being joined to or in contact with the fourth pattern 128b, the second contact 182 not being joined to or in contact with the third pattern 108b (FIG. 2E representing a top view of the device).

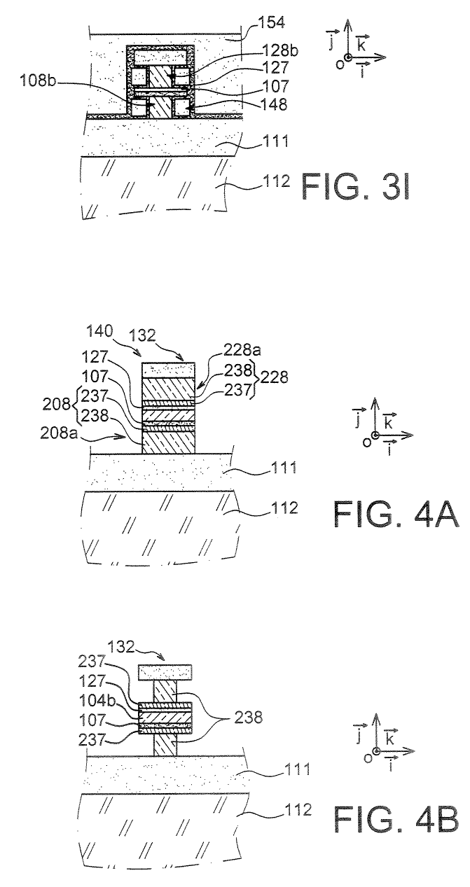

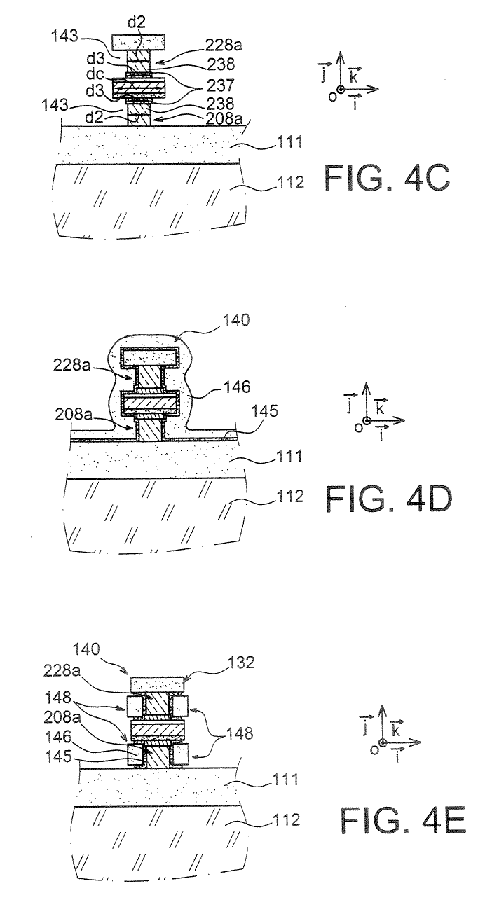

One variant of the example method described above will now be given with reference to FIGS. 4A-4E. In this variant, the first layer of gate material and the second layer of gate material are denoted 208 and 228 respectively and each is formed from a stack of sub layers with different natures or based on different materials, for example a stack of two different sub layers called <<bilayers>>. Said stacks may comprise a sub layer based on a first gate material 237. The first gate material 237 may be chosen for its electricity conducting properties, and for example may be a metallic material such as Ti or TiN or W or WN or Ta or TaN. The other sub layer may be based on a second gate material 238. The second gate material 238 can be selectively etched with respect to the semiconducting layer 104 or it may have good etching selectivity with respect to the semiconducting layer 104. The second gate material 238 may be a semiconducting material. The second gate material 238 may for example be polySiGe, particularly in the case in which the semiconducting layer 104a is based on silicon. The first layer 208 of gate materials 237, 238, and the second layer 228 of gate materials 237, 238 may be formed from bilayers with identical compositions but with different arrangements. In the first layer 208 of gate materials, the arrangement of bilayers 237, 238 may be such that the sub layer of the first gate material 237 is in contact with the first gate dielectric 107 and is supported on the sub layer of the second material 238, the sub layer of the second gate material 238 being supported on the insulating support layer 111. In the second layer 228 of gate materials, the arrangement of the bilayers 237, 238 may be such that the sub layer of the first gate material 237 is in contact with the second gate dielectric 127, while the sub layer of the second gate material 238 is supported on the first gate material 237 and is in contact with the masking pattern 132.

FIG. 4A illustrates the result of an etching step through the masking pattern 132, similar to the etching step illustrated with reference to FIGS. 1J and 1K and described above. Etching done through the pattern 132, may be anisotropic etching of a stack comprising the first layer 208 of gate material, the first layer 107 of gate dielectric, the semiconducting zone 104a, the second layer of gate dielectric 127 and the second layer of gate material 228. Said stack is etched by masking comprising the gate pattern 132 and at least one pattern (not shown) of the gate contact making area so as to reproduce the form of said masking patterns in said stack and to expose the insulating layer 111. After this etching, a first structure 140 is formed comprising patterns 208a, 228a of a double gate under and on the channel semiconducting zone 104b, with a second structure (not shown), comprising contact making zone patterns.

The next step is partial etching of the gate patterns 208a, 228a and particularly patterns 208a, 228a based on the second bilayer material 238. This etching may be an isotropic etching, for example dry etching done using a CF₄ based plasma (FIG. 4B).

The next step is to do another etching of another part of the patterns 208a, 228a, and particularly another part of the patterns 208a, 228a based on a first bilayer material 237. This etching may be isotropic etching, for example wet etching, for example using SC2 etching (FIG. 4C). The other side etching is done such that after etching, the critical dimensions d₂ and d₃ of the parts of the patterns 208a, 228a based on the first material 237 and the parts of the patterns 208a, 228a based on the second material 238 respectively, are similar to each other or are different by not more than 2 nanometers. After these etching operations, the critical dimension of the patterns 208a, 228a of the double gate and the critical dimension of the patterns of the second structure (not shown), are reduced. Cavities 243 are formed on each side of the patterns 208a, 228a. The critical dimension of the patterns 208a, 228a is less than the critical dimension of the channel semiconducting zone 104b. Compared with double gate patterns formed from a single layer of gate material, the use of such a bilayer firstly facilitates making the size of the patterns 208a, 228a smaller than the channel semiconducting zone, by the use of the gate material 238, while enabling improved control over electrical conduction of the channel semiconducting zone 104b due to the use of the metallic gate material 237 (FIG. 4C).

As described for the previous example method, the next step could be to dope the extensions. Insulating spacers 148 can then be formed on each side of the patterns 208a, 228a so as to insulate the double gate from future source and drain regions. These spacers 148 may be made as described previously with reference to FIGS. 1M and 1N, for example by deposition of a first insulating material 145, for example SiO₂, and then by a conforming deposition of a second insulating material 146, for example Si₃N₄, in the cavities 143. The second insulating material 146 is then etched, for example by anisotropic etching. The first insulating material 145 is then partially removed so as to expose the channel semiconducting zone 104b and to keep the insulating zones 148 based on the first insulating material 145 and the second insulating material 146 on each side of the patterns 208a, 228a (FIG. 4E). Steps to silicide the channel structure zones 104b, to form source and drain blocks, for example metallic blocks, on each side of the channel structure 104b like those described previously with reference to FIGS. 1O-1T can then be done to complete the formation of a double gate transistor.

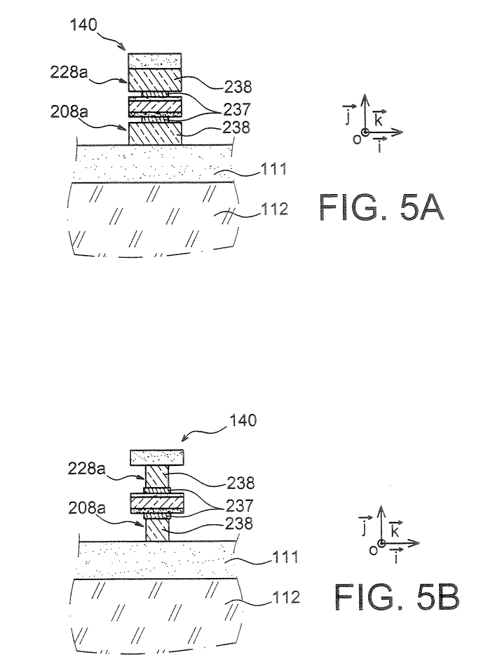

According to one variant of the example method that has just been described with reference to FIGS. 4A to 4E, the step to reduce the patterns 208a, 228a can be done by a first partial etching of the parts of patterns 208a, 228a, based on the first gate material 237. This first partial etching may be an isotropic etching, for example done using an SC2 attack (FIG. 5A). A second partial etching of patterns 208a, 228a and particularly parts of patterns 208a, 228a is then based on the second bilayer material 238. This second etching may be an isotropic etching, for example dry etching done using CF₄ based plasma (FIG. 5B). The next step may then be to complete the formation of a double gate transistor particularly by forming insulating spacers on each side of the double gate patterns 208a, 228a, then on each side of the source and drain blocks, for example metallic blocks, in contact with the channel structure, for example as described previously with reference to FIGS. 1L-1T.

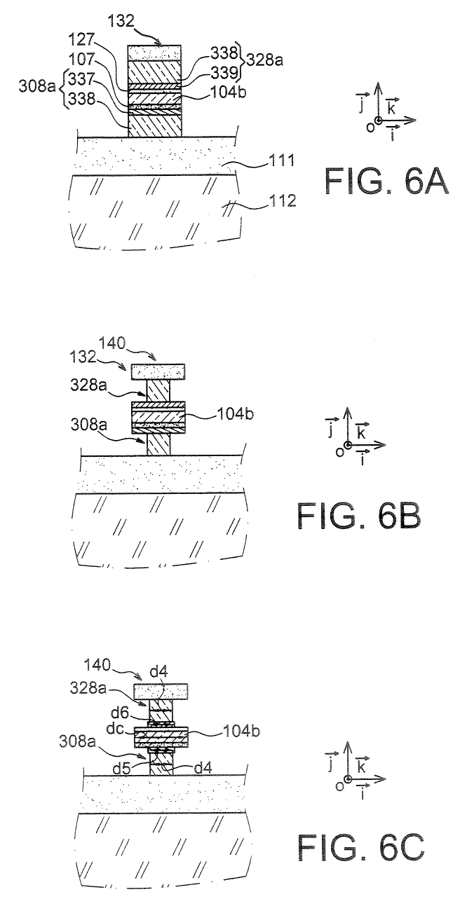

Another variant of the example method described above with reference to FIGS. 4A-4E, will now be presented with reference to FIGS. 6A-6C. In this variant, the first layer of gate materials and the second layer of gate materials are denoted 308 and 328 respectively and are formed from a first stack comprising several sub layers of different materials, for example two sub layers of different materials, and a second stack comprising several sub layers of different materials, for example two sub layers of different materials, the second stack being different from the first stack.

Said first stack of the first layer 308 of gate materials may comprise a sub layer based on a first gate material 337. The first gate material 337 may be chosen for its electricity conducting properties. The first gate material 337 may for example be a metal such as Ti or TiN or W or WN or Ta or TaN. The other sub layer may be based on a second gate material 338 that can be selectively etched with respect to the material of the semiconducting layer 104. The second gate material 338 may for example be a semiconducting material, for example polySiGe, particularly in the case in which the semiconducting zone 104a is based on silicon. In the first layer 308 of gate materials, the arrangement of the material bilayers 337, 338 may be such that the first gate material 337 is in contact with the first gate dielectric 107, while the second gate material 338 is supported on the insulating support layer 111. Said second stack of the second layer 328 of gate materials may comprise a sub layer based on the third gate material 339. The third gate material 339 may be chosen for its electricity conducting properties and for example may be a metal different from the first metal 337, for example chosen from among the Ti, TiN, W, WN, Ta, TaN materials. The other sub layer of the second stack may be based on the second gate material 338 that can be selectively etched with respect to the material from which the semiconducting layer 104 is made. The second gate material 338 may for example be a semiconducting material, for example polySiGe in the case in which the semiconducting zone 104a is based on silicon. In the second layer 328 of gate materials, the arrangement of the bilayer of materials 339, 338 may be such that the third gate material 339 is supported on the second gate dielectric 127, while the second gate material 338 is supported on the third gate material 339.

FIG. 6A illustrates the result of an etching step similar to the etching step illustrated on FIGS. 1J and 1K and described above. This etching may be an anisotropic etching done through patterns 132 and 134 of the mask layer 130, so as to reproduce the shape of said gate patterns 132 and 134 in said stack and to expose the insulating layer 111. For example, the anisotropic etching may be done using Cl₂ (+O₂) or HBr (+O₂) and/or BCl₃ and can be used to form a first structure 140 comprising patterns 308a, 328a, a double gate under and on the channel semiconducting layer 104b respectively, and a second structure comprising gate contact making patterns.

The next step is partial etching of the second material 338 of the bilayers, so as to reduce the parts of the gate patterns 308a, 328a that are based on the second dielectric material 338. This etching may be dry etching, for example done using a CF₄ plasma (FIG. 6B).

The next step is a second partial etching of the first material 337 and the third gate material 339, so as to reduce the parts of the pattern 308a that are based on the first material 337 and to reduce the parts of the pattern 328a that are based on the second material 339. For example, this etching may be done using SC2 (FIG. 6C). The duration of this second etching may be adjusted such that at the end of the second etching, the critical dimension d₄ of the parts of the patterns 328a, 308a based on the second gate material 338 is similar to the critical dimension d₅ of the parts of patterns 308a based on the first gate material 337 and is similar to the critical dimension d₆ of the parts of pattern 328a based on the third gate material 339. <<Similar>> critical dimensions means dimensions that differ by not more than 2 nanometers.

The next step may be to complete the formation of a double gate transistor, particularly by forming insulating spacers on each side of the patterns 308a, 328a of the double gate, and then possibly siliciding the channel semiconducting zone 104b, then forming source and drain blocks, for example metallic blocks, in contact with the channel structure, for example as described above with reference to FIGS. 1L-1T.

One variant formation of source and drain blocks for a double gate transistor comprising a double gate structure will now be described. This variant describes the formation of a device, for example like that described above with reference to FIG. 4E.

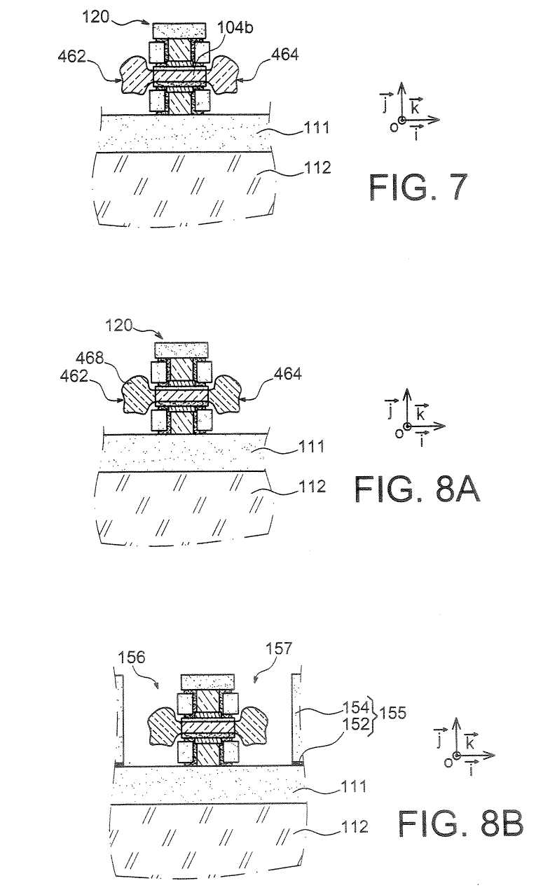

The next step is to form semiconducting blocks 462 and 464 on each side of the first structure 140, at the ends of the channel semiconducting zone 104b. These semiconducting blocks 462, 464 may be formed by epitaxial growth on the edges or ends of the channel semiconducting zone 104b and will be used to form a source region and a drain region respectively, or a region that will belong to a future source or drain region respectively. According to a first variant, the semiconducting blocks 462, 464 may be formed based on the same semiconducting material as the channel semiconducting zone 104b, for example Si in the case in which the channel semiconducting zone 104b is based on Si (FIG. 7).

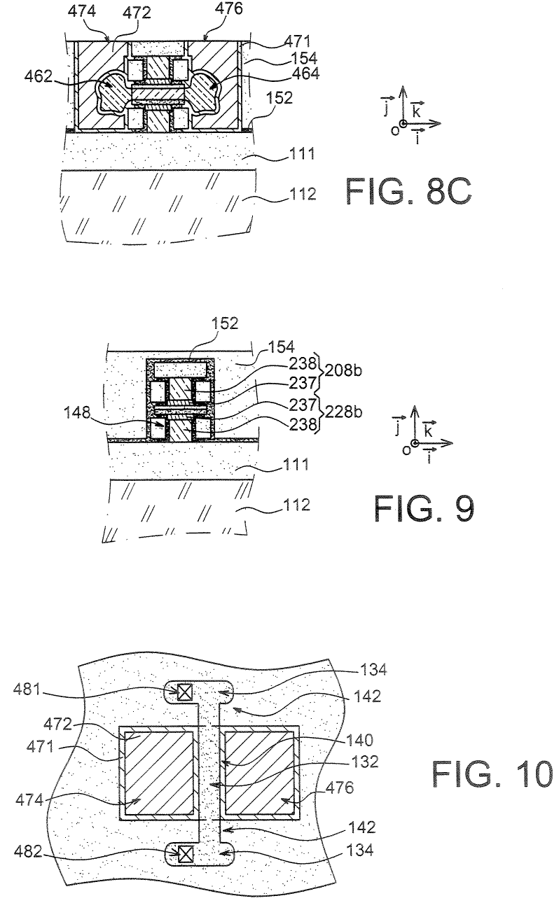

According to one advantageous embodiment, the semiconducting blocks 462, 464 may be formed based on a semiconducting material 468 different from the material used in the channel semiconducting zone 104b, for example Ge or SiGe, particularly in the case in which the channel semiconducting zone 104b is based on Si (FIG. 8A). After the formation of semiconducting blocks 462, 464, it is possible to complete the formation of source and drain regions, for example using a method similar to that described above with reference to FIGS. 1O-1T. The first step is to form a layer 155 so as to cover the structures 140 and 142. Said layer 155 may be formed by deposition of a thin insulating layer (<<liner>>), for example based on SiO₂, followed by another insulating layer called the <<stop layer>>, for example based on Si₃N₄ (the liner and the stop layer being referenced 152), then a thick insulating layer 154, for example based on SiO₂. The next step (FIG. 8B) is to form cavities 156, 157 in the layer 155 exposing the first structure 140, on each side of this first structure. The next step is to form metallic blocks 474, 476, on each side of the first structure 140, and around the semiconducting blocks 462, 464. This can be done by making one or several deposits of metallic materials in the cavities 156, 157. The metallic blocks 474, 476 can be formed firstly for example by deposition of a thin layer based on a first metallic material 471, for example TiN, on the walls and in the bottom of the cavities 156, 157, the thin layer of metallic material 471 being in contact with the first structure and particularly with the semiconducting blocks 462 and 464. A second metallic material 472, for example W, can then be deposited for example in the cavities 156, 157. In a case in which the metallic materials 471, 472 project from the first structure 140, and/or the metallic blocks 474, 476, are adjacent to each other or joined together, a partial removal of the material(s) 160 is possible, particularly above the first structure 140, so as to form separate metallic blocks 474 and 476. This partial removal may be done for example using a CMP step (FIG. 8C). The device formed may also comprise a second structure 142 made of gate contact making zones supported on the insulating layer 111 of the support 112, and joined to the first structure 140. The second structure 142 comprises a third pattern 208b and a fourth pattern 228b joined to the first pattern 208a and to the second pattern 228a respectively of the first structure. The third pattern 208b is formed from the same stack of layers 238, 237 as the first pattern 208a, while the fourth pattern 228b is formed from the same stack of layers 237, 238 as the second pattern 228a (FIG. 9). The method may also include manufacturing of metallic contacts of at least a first metallic contact 481 in contact with a zone of the third pattern 208b, and at least a second metallic contact 482 in contact with a zone of the fourth pattern 228b, on the second structure 142, after the source and the drain zones have been manufactured. The first contact 481 may be formed so as to be in contact with the third pattern 208b without being in contact with the fourth pattern 228b. The second contact 482 may be formed so as to be in contact with the fourth pattern 228b without being in contact with the fourth pattern 228b (FIG. 10). For example, the first contact 481 may be made using steps to form a mask, then etching through this mask so as to form a cavity exposing the third pattern 208b and not exposing the fourth pattern 228b, and then filling in the cavity with at least one metallic material. For example, the second contact 482 may be made using steps to form another mask, then to etch through this other mask so as to form another cavity exposing the fourth pattern 228b but not exposing the third pattern 228b, and then to fill in the other cavity with at least one metallic material.

1. Method for making a microelectronic device provided with at least one double gate structure for a transistor, including the following steps:
a) formation of at least one stack comprising at least one first layer of gate material(s), at least one first gate dielectric layer supported on the first layer of gate material(s), at least one semiconducting zone supported on said first gate dielectric layer, at least one second gate dielectric layer supported on said semiconducting zone and on said first gate dielectric layer, and at least one second layer of gate material(s) supported on the second gate dielectric layer,
b) anisotropic etching of said stack through a mask, so as to make at least one first structure facing the semiconducting zone, comprising a so-called <<channel>> semiconducting zone formed from said etched semiconducting zone, at least one first pattern of a first gate formed from the first etched layer of gate material, and at least one second pattern of a second gate formed from the second etched layer of gate material,
c) isotropic etching of at least part of the first pattern and at least part of the second pattern, selectively with regard to the channel semiconducting zone.

2. Method according to claim 1, said first layer of gate materials being formed from a stack of several sub layers of different materials.

3. Method according to claim 2, said second layer of gate materials being formed from a stack of several sub layers of different materials.

4. Method according to claim 1, in which said first layer of gate materials is formed from a first stack of several sub layers of different materials and the second layer of gate materials is formed from a second stack of several sub layers of different materials, the first stack being different from the second stack and/or comprising at least one material different from the material from which the first stack is formed.

5. Method according to claim 4, the first layer of gate material(s) and/or the second layer of gate material(s) comprising at least one semiconducting material.

6. Method according to claim 5, the isotropic etching in step c) including at least one dry etching step of said semiconducting material using a plasma.

7. Method according to claim 5, said semiconducting material being polySiGe.

8. Method according to claim 5, the first layer of gate material(s) and/or the second layer of gate materials comprising at least one sub layer based on at least one metallic material.

9. Method according to claim 8, isotropic etching in step c) including at least one wet etching step of said sub layer(s) based on metallic material.

10. Method according to claim 7, said semiconducting zone being based on silicon.

11. Method according to claim 1, comprising after step c), the formation of insulating spacers on each side of the first pattern in the first gate and on each side of the second pattern in the second gate.

12. Method according to claim 1, also comprising, after step c), the formation of at least one first zone to act as a source region in contact with the channel semiconducting zone, and at least one second zone to act as drain region, in contact with the channel semiconducting zone.

13. Method set forth in claim 12, formation of said first and second zones including epitaxial growth of semiconducting blocks on the sides of the channel semiconducting zone.

14. Method according to claim 13, the semi-conducting blocks being based on a semiconducting material different from the semiconducting material(s) in the channel semiconducting zone.

15. Method according to claim 12, formation of said first source region zone and said second drain region zone including the following steps:
deposition of at least one layer on the support,
production of cavities in said layer on each side of said first structure,
deposition of one or several metallic materials in the cavities, so as to form at least one first metallic block and at least one second metallic block on each side of the channel semiconducting zone.

16. Method according to claim 1, formation of said stack including the following steps:
deposit the first gate dielectric layer on a semiconducting layer supported on an insulating layer covering a first support,
deposit the first layer of gate material(s) on said first gate dielectric layer,
bond a second support onto the first layer of gate material(s),
remove the first support and part of said insulating layer covering the first support,
etch said semiconducting layer so as to form said semiconducting zone,
deposit the second layer of gate dielectric on said semiconducting zone and on the dielectric layer,
deposit the second layer of gate material(s) on the second gate dielectric layer.

17. Method according to claim 1, in which anisotropic etching step b) also includes: making at least one second structure in a zone of the stack in which the second gate dielectric layer is supported on the first gate dielectric layer, the second structure comprising at least one third pattern formed from the first etched layer of gate material(s) and at least one fourth pattern formed from the second etched layer of gate materials, the third pattern and the fourth pattern being separated by gate dielectric layers.

18. Method set forth in claim 17, also including: formation of at least one first metallic contact on the second structure, in contact with said third pattern without being in contact with said fourth pattern, and at least one second metallic contact, in contact with the fourth pattern, without being in contact with said third pattern.

19. Microelectronic device comprising:
a support,
at least one first structure supported on said support, said first structure comprising:
at least one first pattern of a first gate supported on the support and comprising a first stack of several sub layers of different gate materials,
at least a first layer of gate dielectric supported on said first pattern,
at least one so-called <<channel>> semiconducting zone with a critical dimension larger than the critical dimension of the first pattern, and in which a transistor channel can be formed,
at least one second gate dielectric layer supported on said semiconducting zone,
at least one second pattern of a second gate with a critical dimension less than the critical dimension of the semiconducting zone, the second pattern supported on the second dielectric layer and comprising a second stack of several sub layers of different gate materials.

20. Microelectronic device according to claim 19, the first stack being different from the second stack and/or comprising at least one material different from that of the first stack.

21. Microelectronic device according to claim 20, the first stack and/or the second stack being formed from at least one semiconducting layer.

22. Microelectronic device according to claim 21, said semiconducting sub layer being formed from polySiGe.

23. Microelectronic device according to claim 21, the first stack and/or the second stack being formed from at least one metallic sub layer.

24. Microelectronic device according to claim 19, the first stack being formed from a first metallic sub layer supported on a first semiconducting sub layer, and the second stack being formed from a second semiconducting sub layer supported on a second metallic sub layer, the composition of the first semiconducting sub layer being identical to the composition of the second semiconducting sub layer, and the composition of the first metallic sub layer being different from the composition of the second metallic sub layer.

25. Microelectronic device according to claim 19, also including at least one first zone that can form a transistor source region, at least one second zone that can act as a transistor drain region, the first zone and the second zone comprising at least one first semiconducting block and at least one second semiconducting block, each formed by epitaxy on the channel semiconducting zone.

26. Microelectronic device according to claim 19 also comprising: at least one first zone that can form one transistor source region, at least one second zone that can form a transistor drain region, the first zone and the second zone each comprising at least one first metallic block and at least one second metallic block in contact with said channel semiconducting zone.

27. Microelectronic device according to claim 19 also comprising: at least one first zone that can form a transistor source region, at least one second zone that can form a transistor drain region, the first zone and the second zone comprising at least one first semiconducting block formed by epitaxy on the channel semiconducting zone, and at least one first metallic block in contact with said first semiconducting block, the second zone comprising at least one semiconducting block formed by epitaxy on the channel semiconducting zone, and at least one second metallic block in contact with said second semiconducting block.

28. Microelectronic device according to claim 19, also comprising: insulating spacers on each side of the first pattern of the first gate and on each side of the second pattern of the second gate.

29. Microelectronic device according to claim 19, also comprising: at least one second structure joined to said first structure and comprising:
at least one third pattern joined to said first pattern formed from said first stack of several sub layers of different gate materials,
at least one first gate dielectric layer supported on said third pattern,
at least one second gate dielectric layer supported on said first layer of gate dielectric,
at least one fourth pattern joined to said second pattern and formed from said second stack of several sub layers formed from different gate materials, and supported on said second gate dielectric layer.

30. Microelectronic device according to claim 29, also comprising: at least one first metallic contact, in contact with said third pattern without being in contact with said fourth pattern, and at least one second metallic contact, in contact with the fourth pattern, without being in contact with said third pattern.
